(19) United States
(12) Patent Application Publication
(10) Pub. No.: US 2026/0190864 A1
(43) Pub. Date: Jul. 2, 2026

(54) HAPTIC RESPONSE INTEGRATED CIRCUIT DEVICE WITH PIEZOELECTRIC STRUCTURES

(71) Applicant: Taiwan Semiconductor Manufacturing Company, Ltd., Hsinchu (TW)

(72) Inventors: Chao-Hung Chu, Keelung City (TW); Ching-Hui Lin, Taichung City (TW); Fu-Chun Huang, Zhubei City (TW); Yi-Hsien Chang, Shetou Township (TW); Chun-Ren Cheng, Hsin-Chu City (TW); Shih-Fen Huang, Jhubei (TW); Po-Chen Yeh, New Taipei City (TW)

(21) Appl. No.: 19/004,604

(22) Filed: Dec. 30, 2024

(51) Int. Cl. H10N 30/87; G06F 3/01; H10N 30/00; H10N 30/063; H10N 30/20; H10N 39/00

(52) U.S. Cl. CPC H10N 30/872; G06F 3/016; H10N 30/063; H10N 30/2047; H10N 30/706; H10N 39/00; G06F 2203/0331

(57) ABSTRACT

Some embodiments relate to a haptic response integrated circuit (IC) device that includes a substrate structure and first and second piezoelectric structures. The substrate structure includes a cavity extending downward from an upper side of the substrate structure. The first and second piezoelectric structures are disposed within the substrate structure at opposing lateral sides of the substrate structure and extend laterally into the cavity toward each other. Each piezoelectric structure includes a first electrode, a piezoelectric element disposed on the first electrode, and a second electrode disposed on the piezoelectric element. The device further includes a fluid disposed in the cavity, and a membrane coupled to the upper side of the substrate structure, the membrane sealing the cavity and retaining the fluid.

### BACKGROUND

As development work in artificial reality (AR) and virtual reality (VR) systems continues to progress, one increasingly important area of interest is the development of haptic response devices, which enhance the overall user experience beyond providing strictly visual input to the user. A particular area of concentration is to render such devices light, compact, and comfortable while providing a realistic sense of physical texture, such as for the hands and/or fingers of the user.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1D illustrate perspective views of some embodiments of a haptic response device including a plurality of haptic response integrated circuit (IC) devices, each providing an associated haptic response, according to the present disclosure.

FIGS. 2A through 2D illustrate graphs of example haptic responses of a plurality of haptic response IC devices, according to the present disclosure.

FIG. 3 illustrates a plan view of some embodiments of a portion of a haptic response device including an array of haptic response IC devices, according to the present disclosure.

FIG. 4 illustrates a block diagram of some embodiments of a haptic response device including a plurality of haptic response IC devices, according to the present disclosure.

FIGS. 5A and 5B illustrate schematic side views of some embodiments of a haptic response IC device in associated states during operation, according to the present disclosure.

FIG. 6 illustrates a side view of some embodiments of a haptic response IC device, according to the present disclosure.

FIGS. 7A and 7B illustrate a side view and a plan view, respectively, of some embodiments of an actuating pre-bond structure for a haptic response IC device, according to the present disclosure.

FIGS. 8A through 8S illustrate various side views of some embodiments of an actuating pre-bond structure for a haptic response IC device at various stages of manufacture, according to the present disclosure.

FIGS. 9A and 9B illustrate a side view and a plan view, respectively, of some embodiments of a capping structure for a haptic response IC device, according to the present disclosure.

FIGS. 10A through 10K illustrate various side views of some embodiments of a capping structure for a haptic response IC device at various stages of manufacture, according to the present disclosure.

FIGS. 11A through 11F illustrate various side views of some embodiments of a haptic response IC device at various stages of manufacture using an actuating pre-bond structure and a capping structure, according to the present disclosure.

FIG. 12 illustrates a methodology of forming a haptic response IC device, according to some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some haptic response or feedback devices (e.g., to enhance artificial reality (AR) and/or virtual reality (VR) systems) may be bulky and heavy, often due to the relatively large mechanical components included in such devices. This bulk may cause some level of user discomfort. Further, such devices may provide a level of spatial resolution that may not reasonably support the visual resolution sometimes provided by the associated AR/VR system.

In various embodiments described herein, a haptic response integrated circuit (IC) device includes IC-level piezoelectric structures. Consequently, multiple such IC devices (e.g., arranged in an array) may be employed in a single haptic response device for application on a small area (e.g., a finger or fingertip, a portion of a hand, etc.) of a user. The resulting spatial resolution of such a device may tend to be more realistic from the user's perspective. Additionally, the weight of such a device may be relatively light, thus promoting user comfort, thus enhancing the overall user experience.

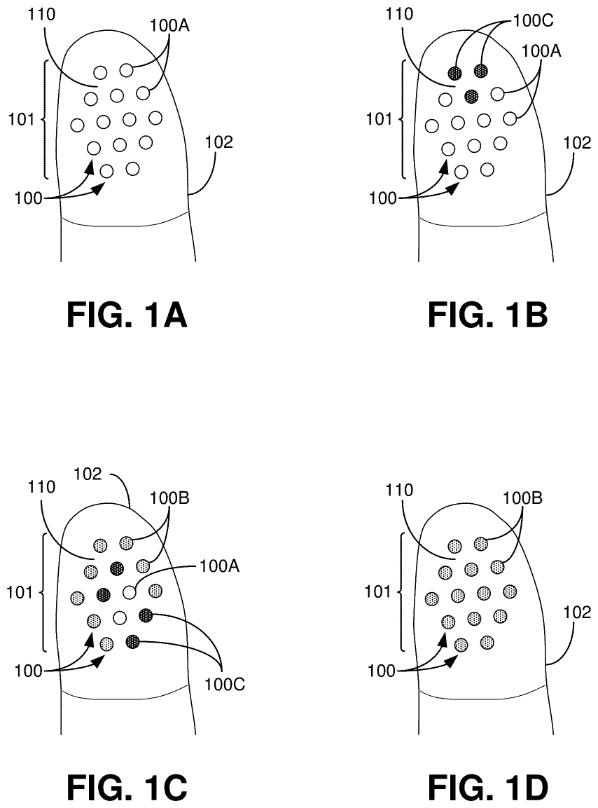

FIGS. 1A through 1D illustrate perspective views of some embodiments of a haptic response device 110 including a plurality of haptic response integrated circuit (IC) devices 100, each providing an associated haptic response to a finger of a user, according to the present disclosure. As depicted in these figures, IC devices 100 may be arranged as an array 101 (e.g., by attachment to a flexible medium 102, such as an elastic fabric or other flexible material).

Each of FIGS. 1A through 1D depict a different haptic response or feedback being provided to a user finger. In each of the examples, an IC device 100 represented by a clear or empty circle indicates an IC device 100A that is in a inactivate or “flat” state. Further, an IC device 100 represented by a moderately shaded circle indicates an IC device 100B that is in a moderately inactivated or protruded state. In addition, an IC device 100 represented by a heavily shaded circle indicates an IC device 100C that is in a strongly inactivated or protruded state.

Accordingly, FIG. 1A depicts an array 101 of IC devices 100A that are in an inactivated state. In some examples, FIG. 1A may thus illustrate a situation in which haptic response device 110 represents a lack of a surface (e.g., a “no-touch” feeling) for a finger of the user. FIG. 1B, on the other hand, illustrates the representation of a sharp texture to a fingertip of the user by way of a small number of IC devices 100C in a heavily activated state, with remaining IC devices 100C in an inactive state. FIG. 1C illustrates the representation of a complex texture by way of a mixture of inactive IC devices 100A, moderately activated IC devices 100B, and heavily activated IC devices 100C. FIG. 1D illustrates the representation of a smooth surface by way of all IC devices 100B operating in a moderately activated state.

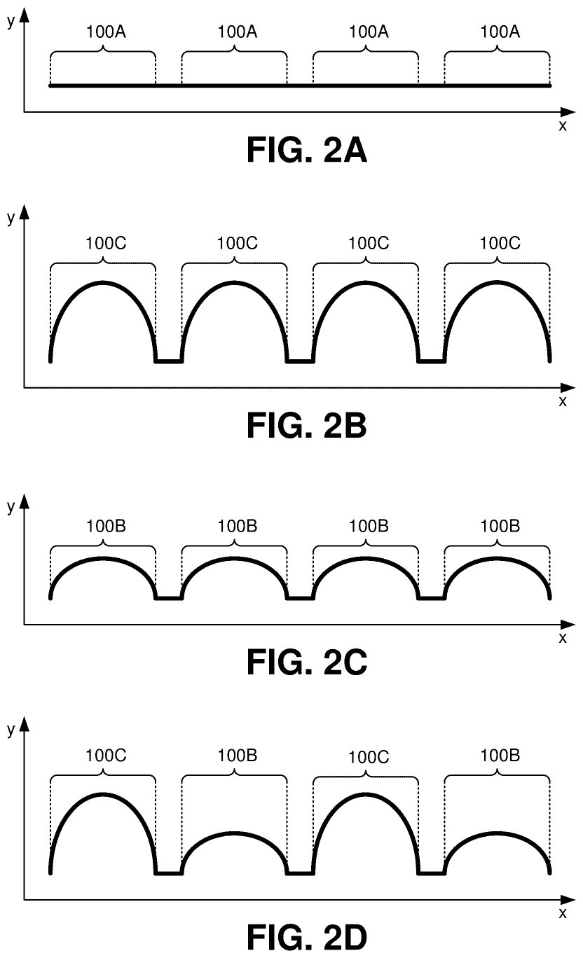

FIGS. 2A through 2D illustrate graphs of example haptic responses of a plurality of haptic response IC devices 100, according to the present disclosure. More specifically, each of FIGS. 2A through 2D depicts a side view, in which the x-direction is along a row of an array 101 of IC devices 100 and the y-direction is toward the skin of the user. For example, FIG. 2A illustrates four inactivated IC devices 100A (e.g., representing a lack of a surface being touched), FIG. 2B illustrates four heavily activated IC devices 100C (e.g., representing a sharp or bumpy surface), FIG. 2C illustrates four moderately activated IC devices 100B (e.g., representing a smooth surface), and FIG. 2D illustrates a mixture of strongly activated IC devices 100C and moderately activated IC devices 100B (e.g., representing a complex or irregular surface).

While the examples of FIGS. 1A through 1D and FIGS. 2A through 2D imply the use of three activation states (e.g., inactivated, moderately activated, and heavily or strongly activated), IC devices 100 may exhibit a greater number of states (e.g., 4, 5, and so on) in some embodiments to provide more subtle differences in various surface textures that may be presented to the user.

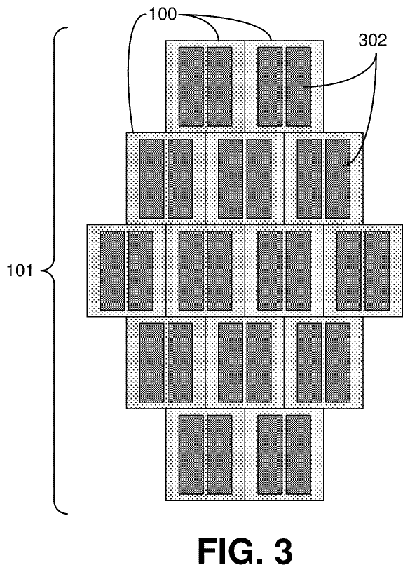

FIG. 3 illustrates a plan view of some embodiments of a portion of a haptic response device including an array 101 of a plurality of haptic response IC devices 100, according to the present disclosure. While array 101 is arranged in a diamond-like pattern in a manner similar to that of array 101 of FIGS. 1A through 1D, other patterns or arrangements for an array 101 of IC devices 100 are possible in other embodiments.

As depicted in FIG. 3, each IC device 100 may include a plurality of (e.g., two) piezoelectric structures 302 that operate to provide the representation of texture for each IC device 100, as discussed above. Various embodiments of piezoelectric structures 302 and associated IC devices 100 are described in greater detail below.

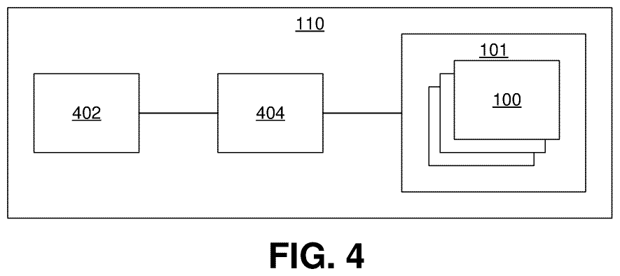

FIG. 4 illustrates a block diagram of some embodiments of a haptic response device 110 including a plurality of haptic response IC devices 100, according to the present disclosure. More specifically, as described above, IC devices 100 may be organized as an array 101 (e.g., arranged in a particular pattern on a flexible substrate) for contact with a user.

In some embodiments, haptic response device 110 may also include a high-voltage device 404 and a core (e.g., logic) device 402. In some embodiments, core device 402 may provide or generate operational signals that control operation (e.g., timing, magnitude, frequency, and so on) of the piezoelectric structures of each IC device 100. In turn, in some embodiments, high-voltage device 404 may generate high-voltage signals derived from the operational signals received from core device 402. The high-voltage signals may then be provided to IC devices 100 to drive the piezoelectric structures of each IC device 100 (e.g., piezoelectric structures 302 of FIG. 3).

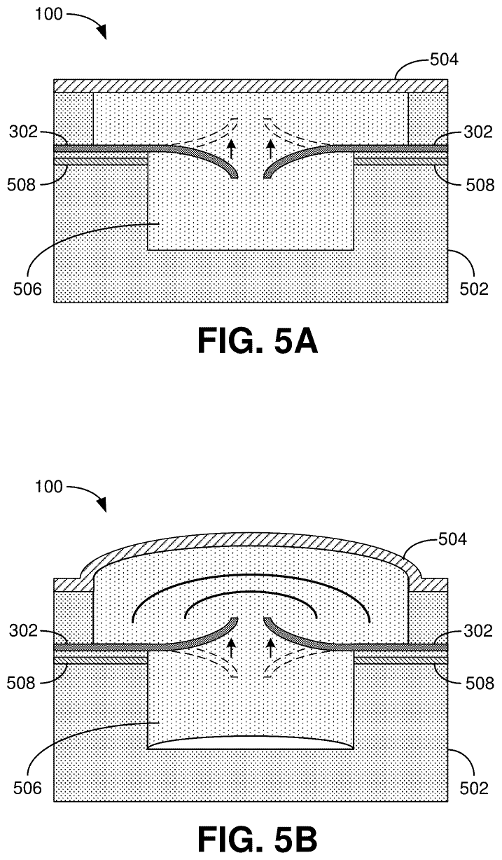

FIGS. 5A and 5B illustrate schematic side views of some embodiments of a haptic response IC device 100 in associated states during operation, according to the present disclosure. For example, a substrate 502 may include or define a cavity that is filled with a fluid 506 (e.g., a non-compressible liquid). Further, in some embodiments, substrate 502 may actually be two substrate portions coupled together by way of a bonding layer or structure 508. Also, a membrane 504 (e.g., a flexible film or other membrane) may cover an opening of the cavity to retain fluid 506.

Further, piezoelectric structures 302 may extend from opposing sides or walls of substrate 502 toward each other within the cavity. In some embodiments, each piezoelectric structure 302 may form a cantilever structure that includes a free end that moves up and/or down in response to a voltage applied thereacross. For example, at one voltage, piezoelectric structures 302 may deflect downward, as shown in FIG. 5A. At another voltage, as depicted in FIG. 5B, piezoelectric structures 302 may deflect upward, thus possibly urging fluid 506 upward to facilitate outward protrusion of membrane 504 to be sensed by the user. In other embodiments, the greater the displacement of piezoelectric structures 302 in any direction may cause distention or protrusion of membrane 504. In some embodiments, piezoelectric structures 302 may be described as “propellers” that cause at least temporary protrusion or deformation of membrane 504.

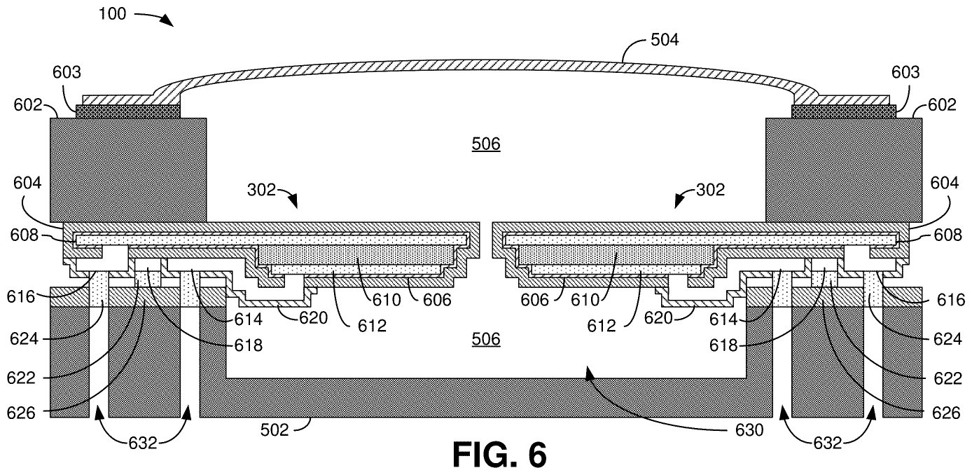

FIG. 6 illustrates a side view of some embodiments of a haptic response IC device 100, according to the present disclosure. Included in IC device 100 is a substrate structure that includes a first substrate 602 disposed over a second substrate 502. In some embodiments, first substrate 602 and second substrate 502 may include silicon (Si) or another semiconductor material. First substrate 602 and second substrate 502 may include or define a cavity 630 that includes a fluid 506 (e.g., a non-compressible liquid, such as water, oil, or the like). Access to cavity 630 (e.g., for introduction of fluid 506) may be provided by way of an opening in an upper side of first substrate 602. Thereafter, fluid 506 may be retained inside cavity 630 by way of a membrane 504 (e.g., a flexible membrane impenetrable by fluid 506). Membrane 504 may be affixed to the upper side of first substrate 602 by way of an adhesive 603. Further, as described above, membrane 504 may serve as the physical haptic interface between IC device 100 and the user.

Further, first and second piezoelectric structures 302 may be disposed between first substrate 602 and second substrate 502 at opposite lateral sides thereof. More specifically, a first portion of each of first and second piezoelectric structures 302 may be positioned between first substrate 602 and second substrate 502, while a second portion of each of first and second piezoelectric structures 302 may extend laterally toward the opposing piezoelectric structure 302 (e.g., toward a central region of cavity 630). Each of first and second piezoelectric structures 302 may include a first (e.g., bottom) electrode 612, a piezoelectric element 610 disposed over first electrode 612, and a second (e.g., top) electrode 608 disposed over piezoelectric element 610. In some embodiments, piezoelectric element 610 may include one or more piezoelectric materials, including but not limited to lead zirconate titanate (PZT), lithium tantalate (LT or LiTaO₃), lead magnesium niobate (PMN), potassium sodium niobate (KNN), lead meta niobate (LMN), aluminum scandium nitride (AlScN), or another piezoelectric material (e.g., a piezoelectric ceramic material). Further, in some embodiments, first electrode 612 and second electrode 608 may include, but are not limited to, platinum (Pt), molybdenum (Mo), iridium (Ir), lithium nickel dioxide (LNO), ruthenium(IV) oxide (RuO₂), a conductive metal, or another conductive material. In some embodiments, a voltage across first electrode 612 and second electrode 608 may create a vertically oriented electric field in piezoelectric element 610 that causes the portion of associated piezoelectric structure 302 in cavity 630 to deflect upward or downward, depending on the magnitude and polarity of the voltage.

Each piezoelectric structure 302 may further include a barrier/adhesion structure 606 substantially surrounding the combination or stack of first electrode 612, piezoelectric element 610, and second electrode 608. In some embodiments, barrier/adhesion structure 606 may include aluminum oxide (Al₂O₃), titanium oxide (TiO₂), zirconium oxide (ZrO₂), ruthenium(IV) oxide (RuO₂), zinc oxide (ZnO), chromic oxide (Cr₂O₃), or the like.

Further, in some embodiments, an insulator structure 604 may substantially cover barrier/adhesion structure 606 enveloping each piezoelectric structure 302. Insulator structure 604 may include silicon oxide (SiOₓ) (e.g., silicon dioxide (SiO₂)), silicon nitride (SiN), aluminum oxide (Al₂O₃), boron nitride (BN), or another insulating material.

In some embodiments, barrier/adhesion structure 606 and insulator structure 604 may define openings through which conductive pads may extend to connect to first electrode 612 and second electrode 608. More specifically, for each piezoelectric structure 302, a first conductive pad 614 may be connected to first electrode 612 through barrier/adhesion structure 606 and insulator structure 604. Similarly, for each piezoelectric structure 302, a second conductive pad 616 may be connected to second electrode 608 through barrier/adhesion structure 606 and insulator structure 604. In some embodiments, each conductive pad may be routed some distance along insulator structure 604 to a location that is accessible external to IC device 100. For example, as shown in FIG. 6, first conductive pad 614 is routed from a position within cavity 630 to a position outside cavity 630, while second conductive pad 616 is routed to a position closer to an outer lateral boundary of IC device 100.

In some embodiments, conductive pads 614 and 616 may include a metal, metal alloy, or other conductive material, possibly in conjunction with an adhesion layer (e.g., to adhere the metal, metal alloy, or other conductive material to insulator structure 604). In some embodiments, the metal, metal alloy, or other conductive material associated with conductive pads 614 and 616 may include, but is not limited to, tin (Sn), gold (Au), an aluminum-copper (AlCu) alloy, a gold-copper-tin (AuCuSn) alloy, or the like. Also, in some embodiments, the adhesion layer associated with conductive pads 614 and 616 may include, but is not limited to, titanium (Ti), chromium (Cr), zirconium (Zr), or titanium nitride (TiN) (e.g., in the case of the conductive material being an AlCu alloy), or another adhesion material (e.g., for other metals or metal alloys).

Further, in some embodiments, portions of conductive pads 614 and 616 associated with each piezoelectric structure 302 may be covered with a passivation layer 620 (e.g., to protect at least conductive pads 614 and 616 from subsequent IC processing operations when fabricating IC device 100). In addition, in some embodiments, passivation layer 620 may include silicon nitride (SiN), aluminum nitride (AlN), hafnium oxide (HfOₓ), zinc oxide (ZnO), silicon carbide (SiC), and/or the like. Also, as illustrated in FIG. 6, passivation layer 620 for each piezoelectric structure 302 may have an opening for each conductive pad 614 and 616 to facilitate conductive connection thereto.

With respect to piezoelectric structures 302, an additional conductive pad, termed a bonding pad 618 (e.g., similar to the bonding layer or structure 508 of FIGS. 5A and 5B), may be disposed adjacent insulator structure 604 and exposed through an associated opening in passivation layer 620. In some embodiments, bonding pad 618 may be positioned laterally between first conductive pad 614 and second conductive pad 616 of both piezoelectric structures 302. Accordingly, as described in greater detail below, bonding pad 618 may form a continuous enclosing conductive structure laterally encircling cavity 630.

As is the case with conductive pads 614 and 616, bonding pad 618 may include a metal, metal alloy, or other conductive material, possibly in conjunction with an adhesion layer (e.g., to adhere the metal, metal alloy, or other conductive material to insulator structure 604). In some embodiments, the metal, metal alloy, or other conductive material may include tin (Sn), gold (Au), an aluminum-copper (AlCu) alloy, a gold-copper-tin (AuCuSn) alloy, or the like. Also, in some embodiments, the adhesion layer may include titanium (Ti), chromium (Cr), zirconium (Zr), titanium nitride (TiN), or another adhesion material.

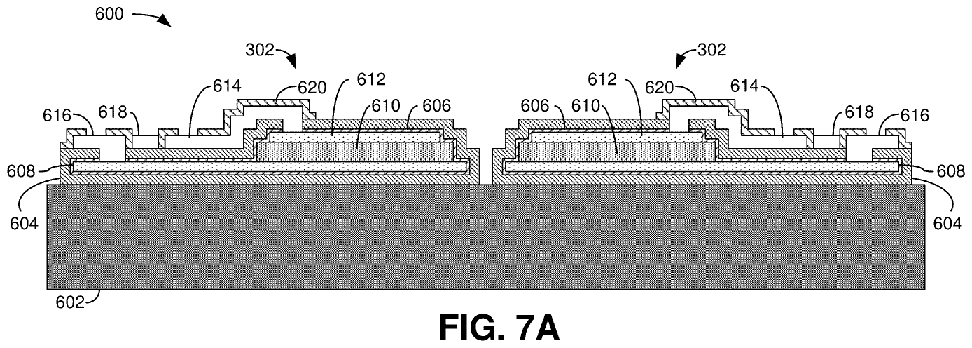

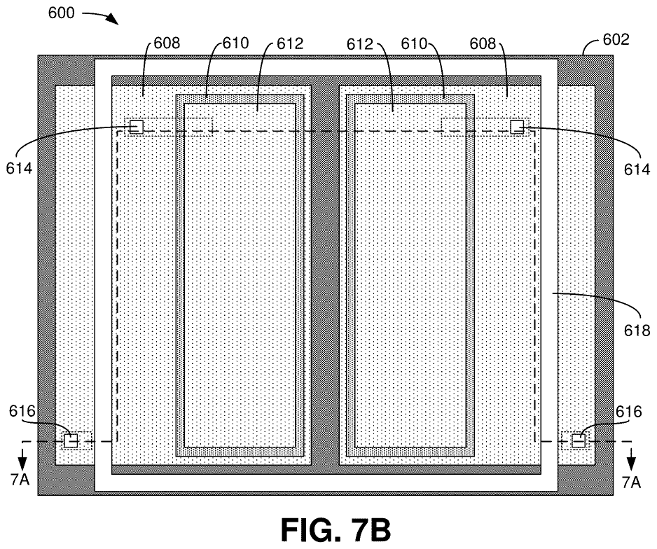

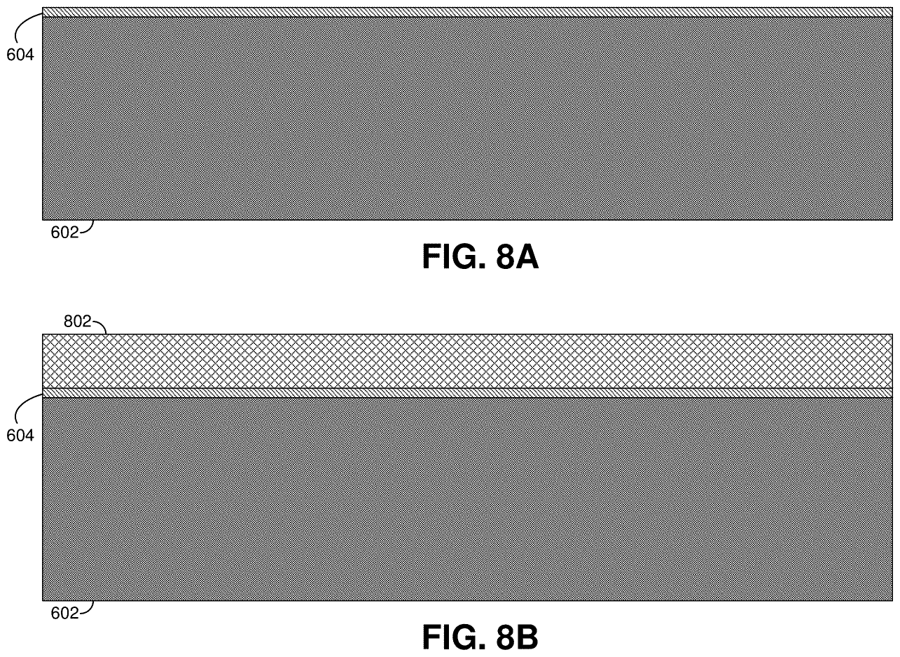

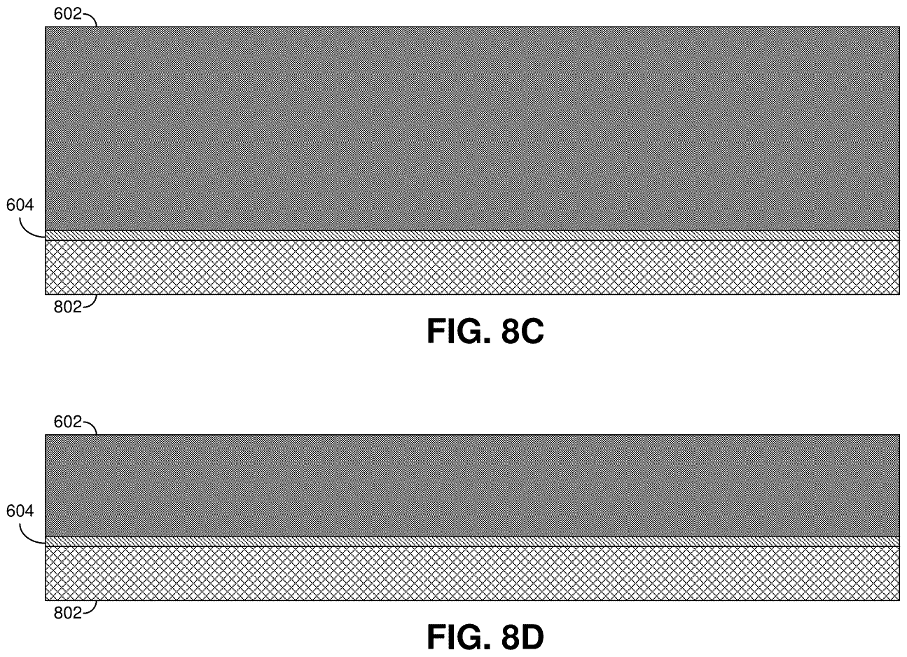

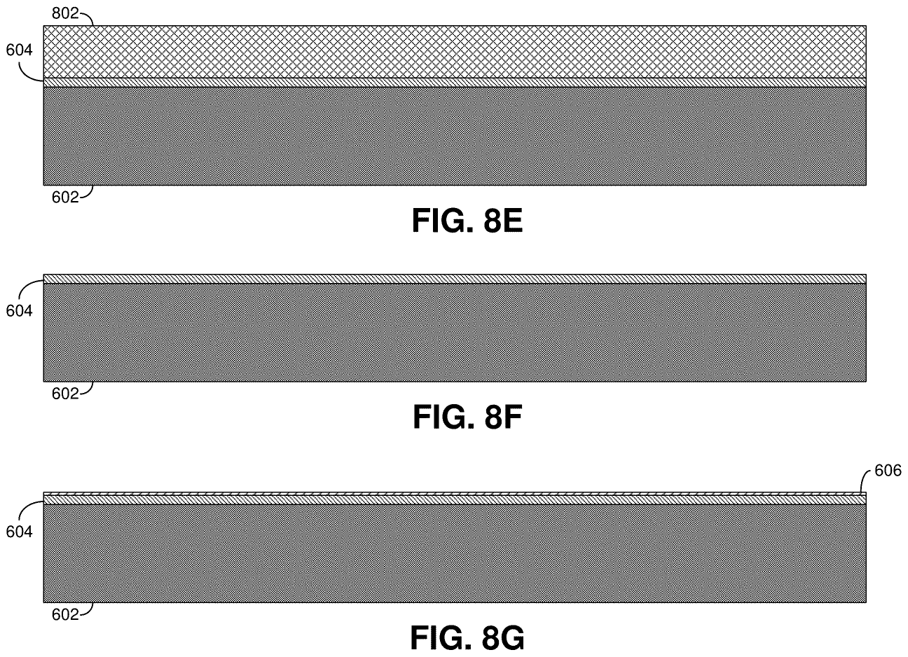

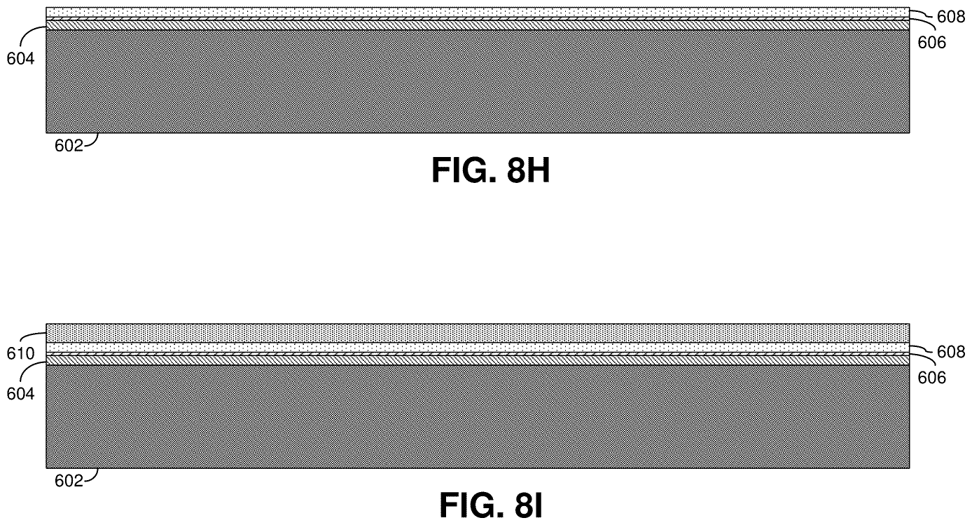

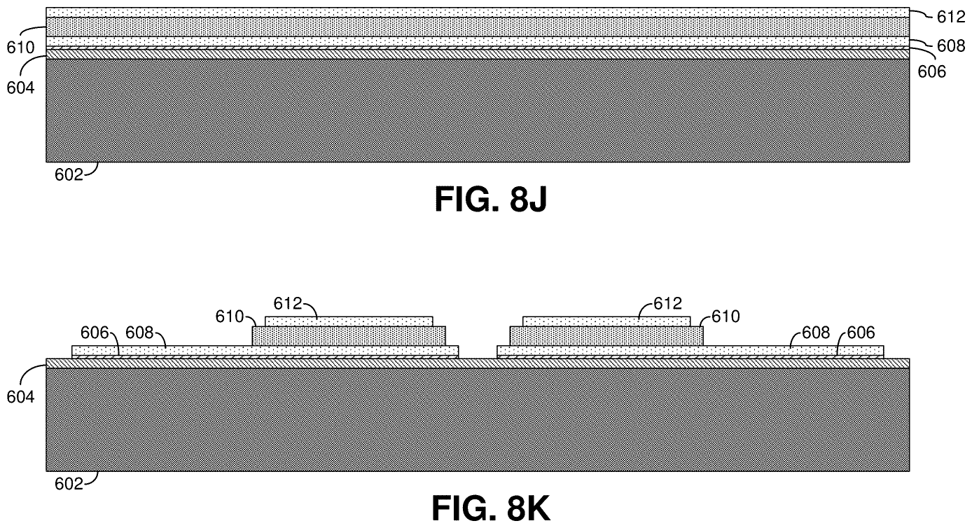

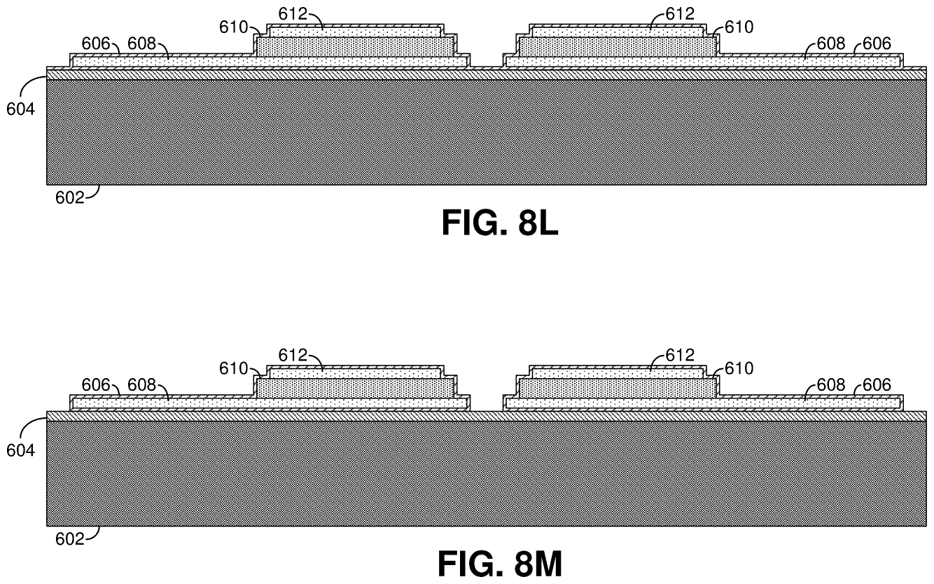

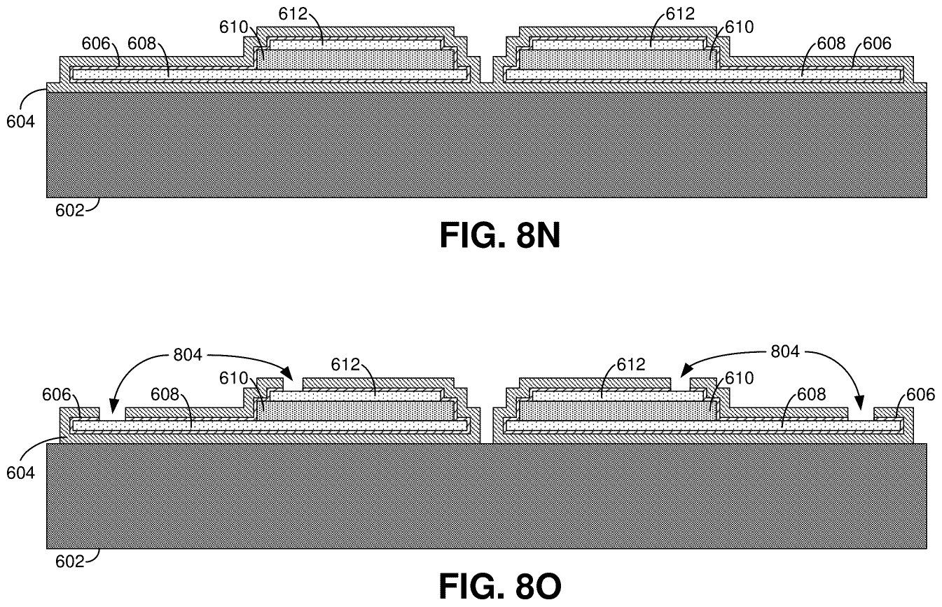

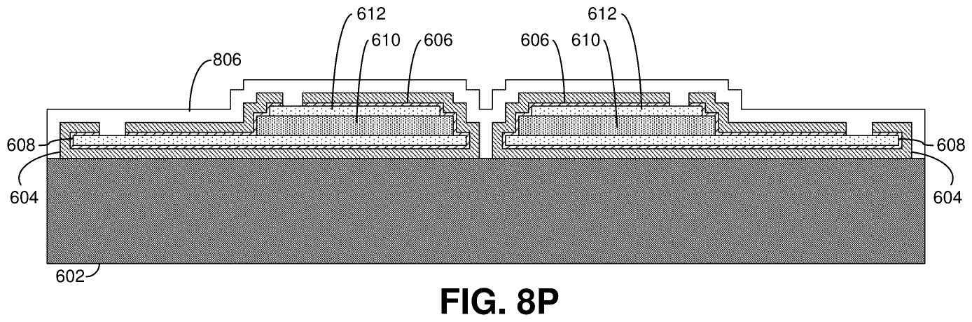

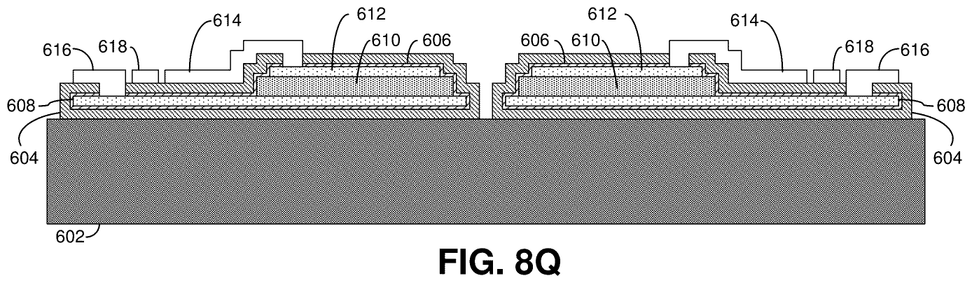

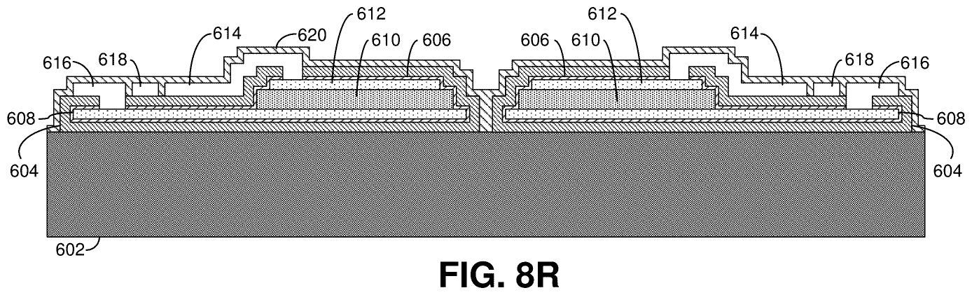

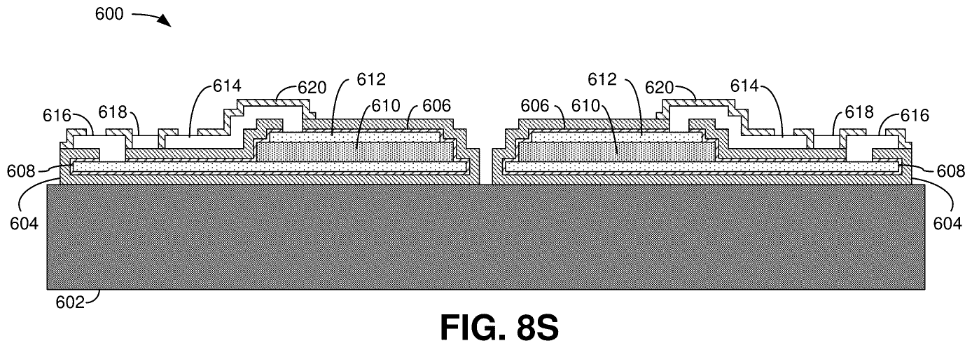

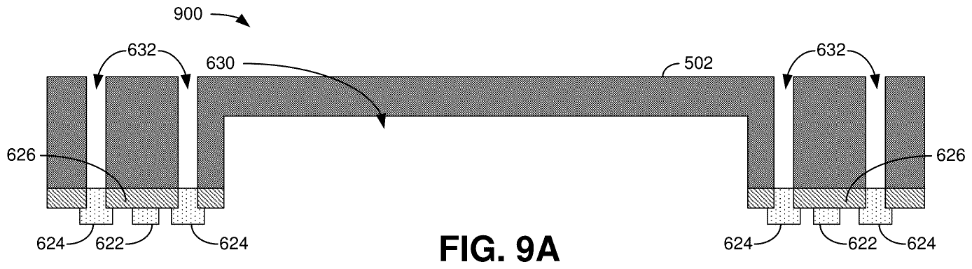

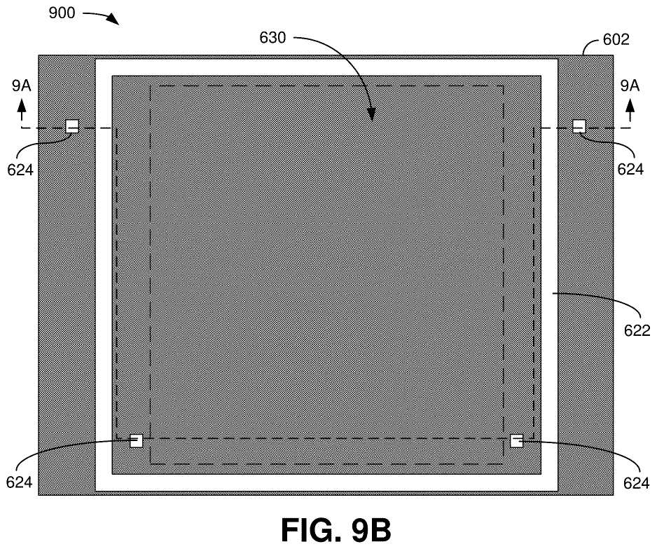

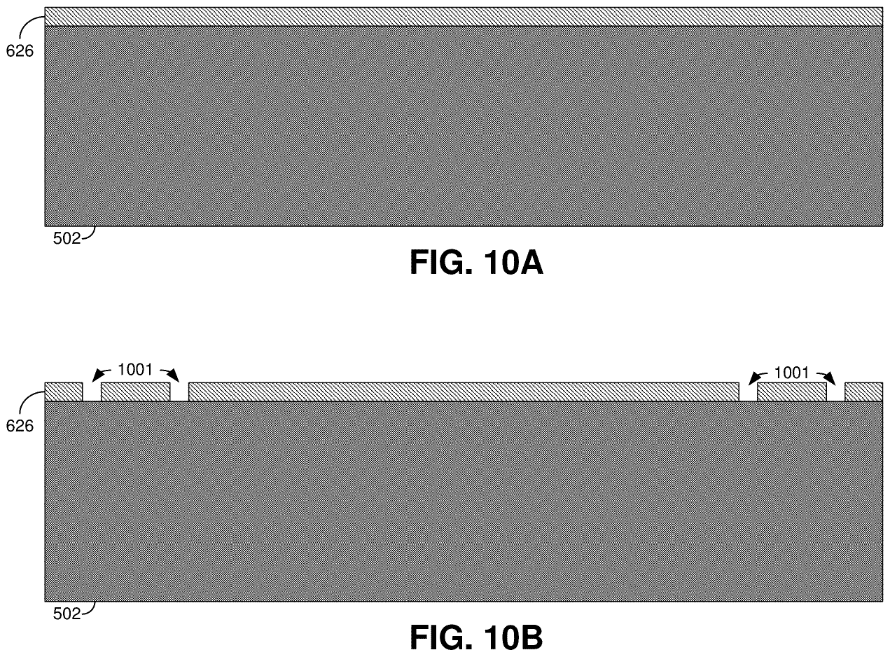

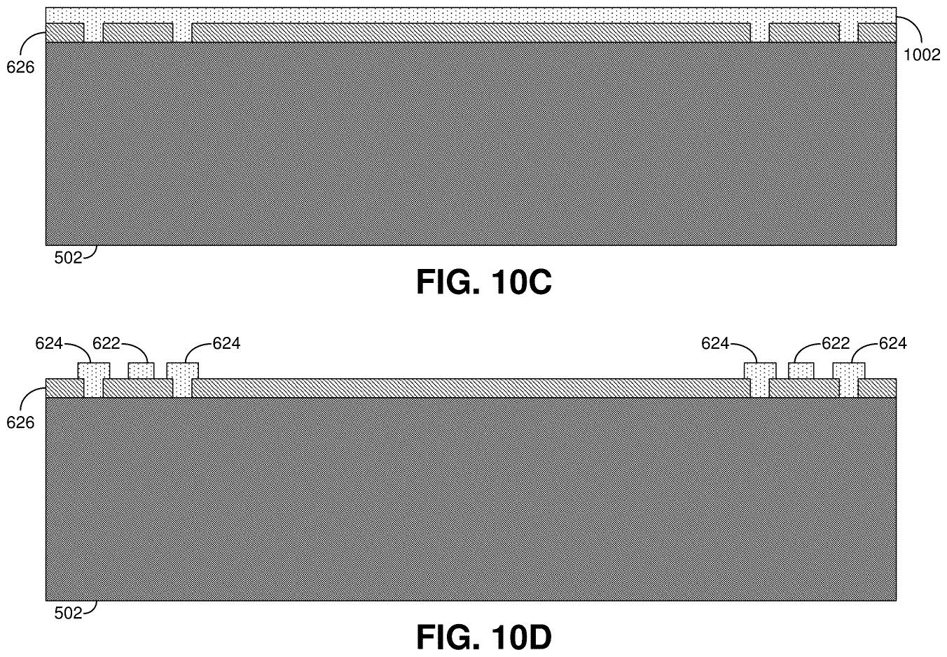

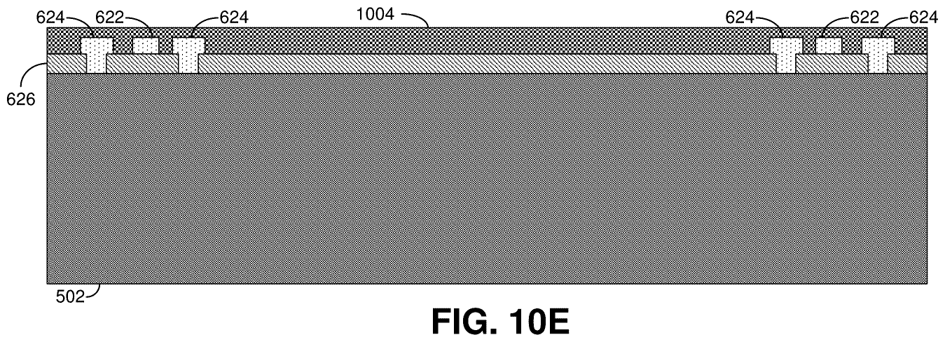

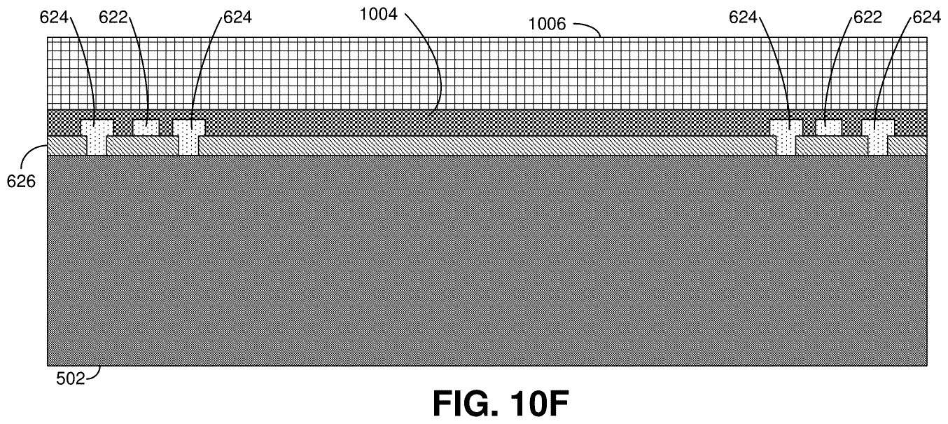

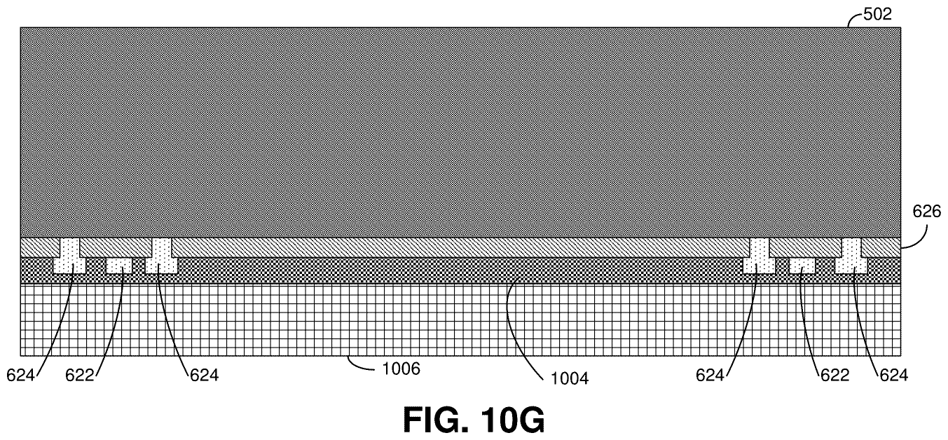

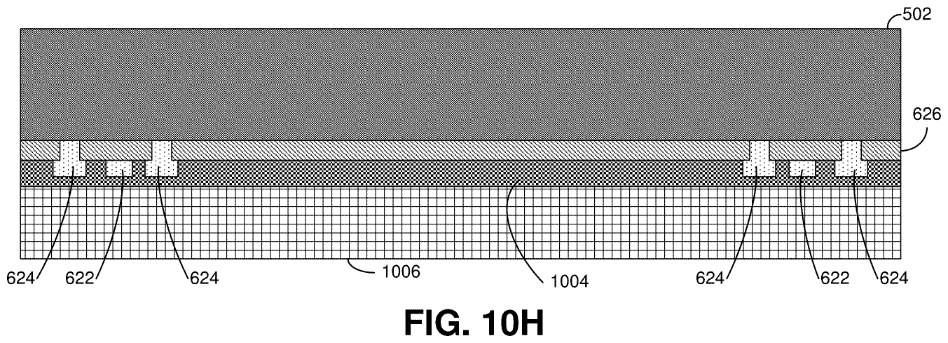

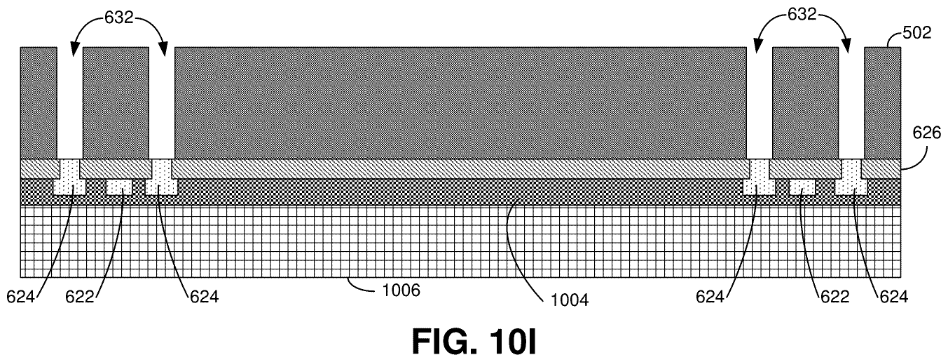

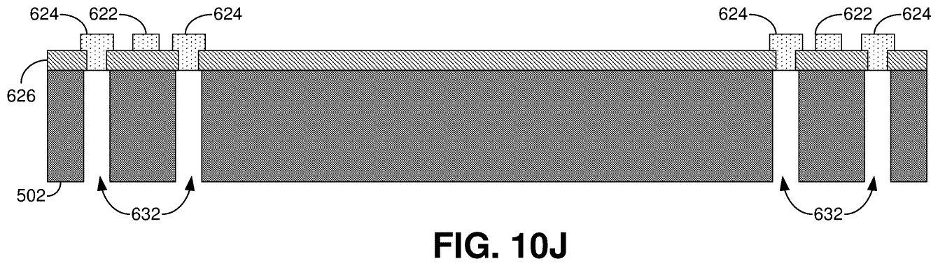

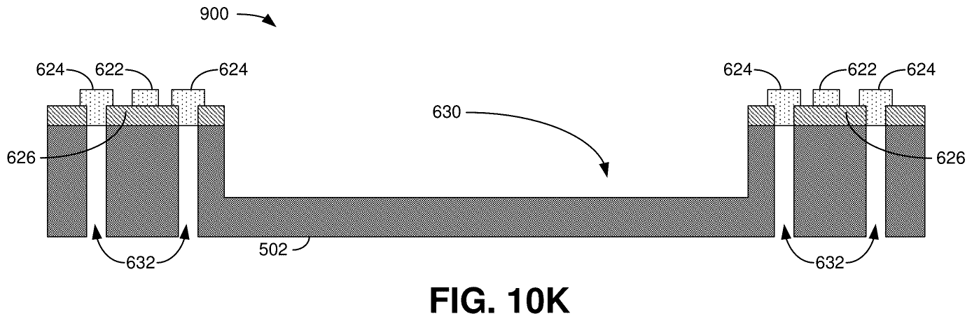

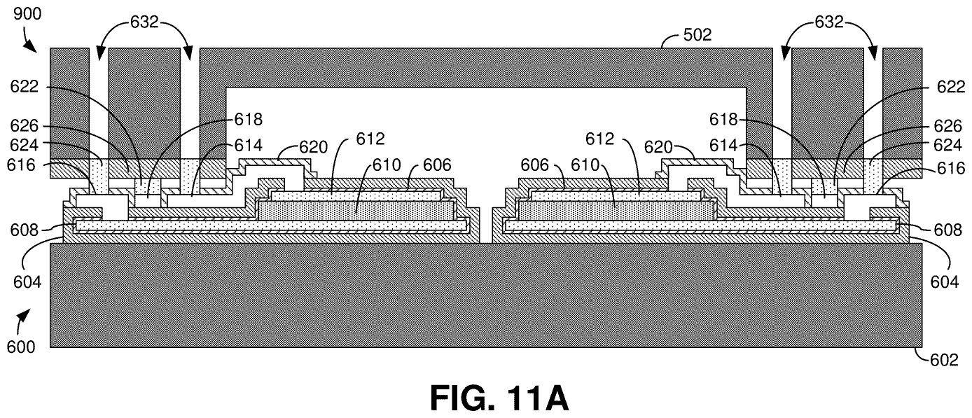

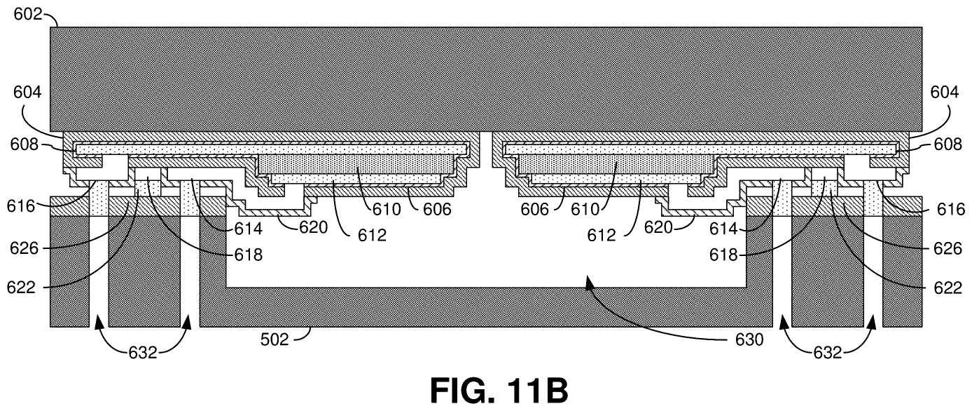

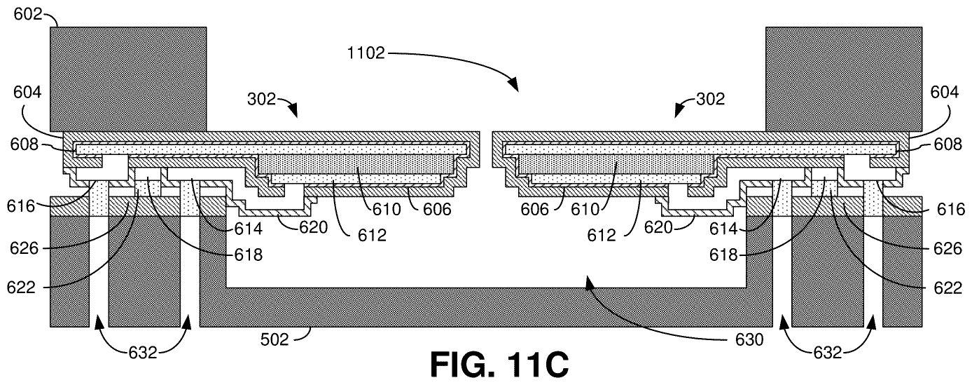

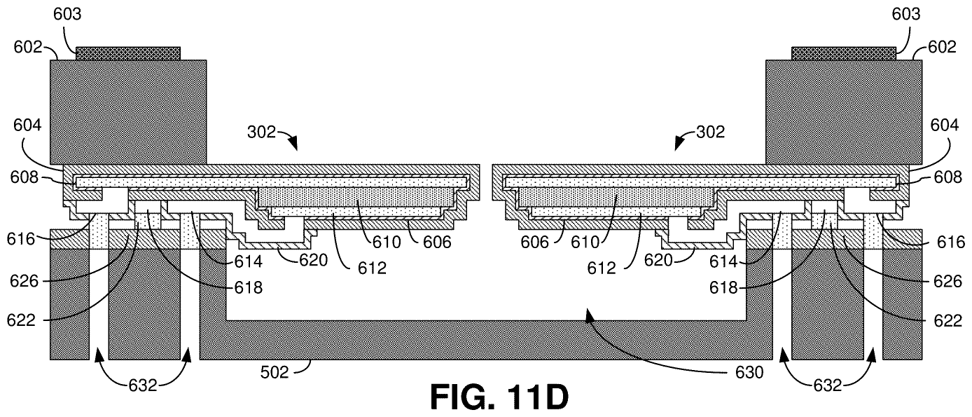

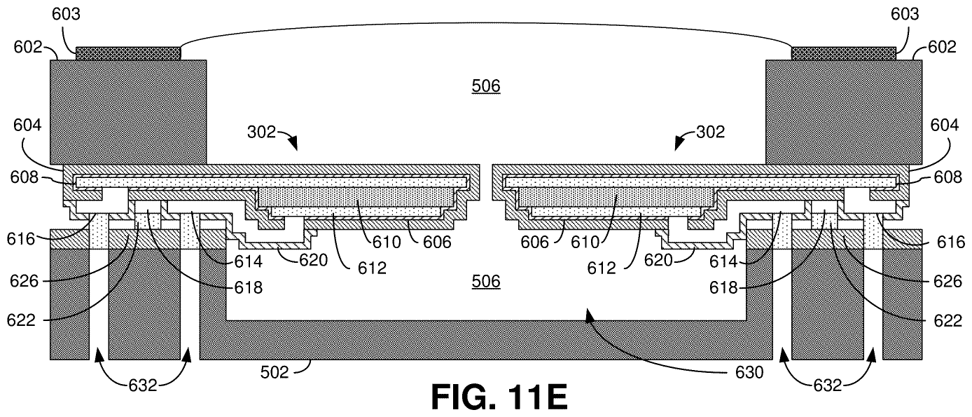

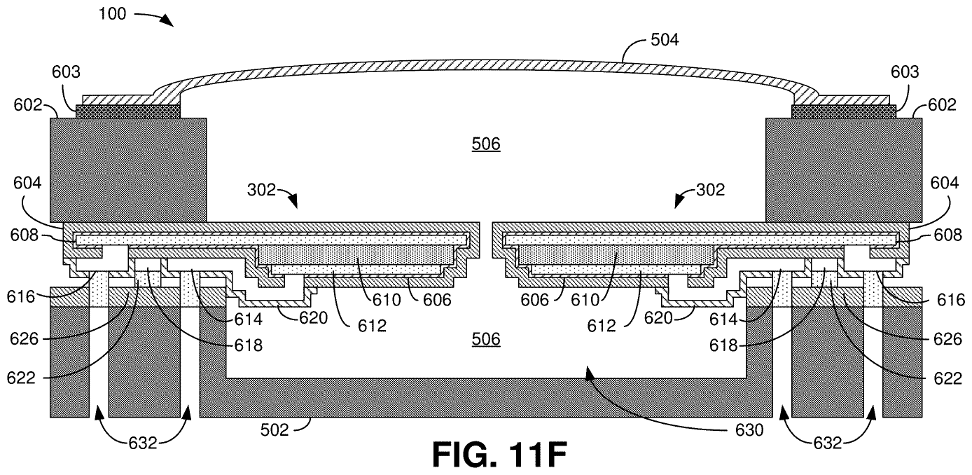

In some embodiments, the above-described portion of IC device 100 is referred to below in conjunction with FIGS. 7A and 7B, and FIGS. 8A through 8S as a actuating pre-bond structure (e.g., actuating pre-bond structure 600 of FIGS. 7A and 7B) that is joined with a capping structure (e.g., capping structure 900 of FIGS. 9A and 9B), which is described below in connection with FIGS. 9A and 9B, and FIGS. 10A through 10K. The joining and subsequent processing of the combined structure to form IC device 100 is further discussed in relation to FIGS. 11A through 11F.

As further depicted in FIG. 6, with respect to the capping structure, disposed over second substrate 502 may be an insulating/adhesion structure 626. In some embodiments, insulating/adhesion structure 626 may include titanium dioxide (TiO₂), zinc oxide (ZnO), aluminum oxide (Al₂O₃), chromic oxide (Cr₂O₃), and/or another insulating material.

Further, in some embodiments, second substrate 502 and insulating/adhesion structure 626 may jointly include or define trenches 632 extending vertically therethrough and laterally located to align with each first conductive pad 614 and second conductive pad 616 of each piezoelectric structure 302. Moreover, in some embodiments, each of conductive pads 614 and 616 may be joined with the capping structure by way of a corresponding bump pad structure 624. In addition, in some embodiments, bonding pad 618 may be joined with the capping structure by way of a bump pad structure 622. More specifically, bonding pad 618 may be joined by a bump pad structure 622 to an upper side of insulating/adhesion structure 626, while each conductive pad 614 and 616 of each piezoelectric structure 302 may be coupled to a corresponding trench 632 by way of an associated bump pad structure 624. Accordingly, in some embodiments, each trench 632 may provide a path through which a conductive material may be formed or deposited to provide driving signals (e.g., high-voltage signals, such as those provided by high-voltage device 404 of FIG. 4) to each first electrode 612 and second electrode 608 to operate piezoelectric structures 302.

In some embodiments, bump pad structures 622 and 624 may include a conductive dielectric material and/or a combination of an adhesion layer and a metal or metal alloy portion. For example, the conductive dielectric material for bump pad structures 622 and 624 may include doped germanium (Ge), doped silicon (Si), another doped semiconductor material, or another conductive dielectric material. An adhesion layer for bump pad structures 622 and 624 may include titanium (Ti), chromium (Cr), nickel (Ni), and/or tantalum (Ta) (e.g., which may be particularly compatible with a metal alloy such as aluminum-copper (AlCu)), or another conductive adhesion material. Further, in some embodiments, a metal or metal alloy for bump pad structures 622 and 624 may include tin (Sn), gold (Au), an aluminum-copper (AlCu) alloy, a gold-copper-tin (AuCuSn) alloy, or the like. Further, in some embodiments, various combinations of such conductive dielectric and/or metallic material for bump pad structures 622 and 624 may be employed, such as doped germanium or doped silicon with an aluminum-copper alloy, gold with an aluminum-copper alloy, or gold with tin. Other combinations of the various materials listed above are also possible for use as bump pad structures 622 and 624.

FIGS. 7A and 7B illustrate a side view and a plan view, respectively, of some embodiments of an actuating pre-bond structure 600 for a haptic response IC device 100, according to the present disclosure. More specifically, FIG. 7B is presented as looking downward toward an upper surface of actuating pre-bond structure 600, as presented in FIG. 7A. As described above, actuating pre-bond structure 600 is shown in FIGS. 7A and 7B in a state just prior to joining with a capping structure and subsequent processing. As shown, actuating pre-bond structure 600 includes first substrate 602 prior to the formation of cavity 630 of FIG. 6, along with piezoelectric structures 302, barrier/adhesion structures 606, insulator structures 604, first conductive pads 614, second conductive pads 616, bonding pad 618, and passivation layers 620.

As particularly shown in the plan view of FIG. 7B, first conductive pads 614 may lie in a separate vertical plane from second conductive pads 616. Also, in FIG. 7B, first conductive pads 614 and second conductive pads 616 are shown in dotted outline, and a portion of first conductive pads 614 and second conductive pads 616 associated with openings in passivation layers 620 are shown as solid-line squares. In addition, bonding pad 618 is illustrated as a rectangular wire that passes between first conductive pad 614 and second conductive pad 616 of each piezoelectric structure, and encloses first electrodes 612 and piezoelectric elements 610 of the piezoelectric structures.

Additionally, each associated element of a piezoelectric structure (e.g., first electrode 612, piezoelectric element 610, and second electrode 608) is shown in FIG. 7B as a rectangular region. Further, in some embodiments, second electrode 608 has a greater area than piezoelectric element 610 and has a perimeter that encloses a perimeter of piezoelectric element 610. Similarly, in some embodiments, piezoelectric element 610 has a greater area than first electrode 612 and has a perimeter that encloses a perimeter of first electrode 612.

FIGS. 8A through 8S illustrate various side views of some embodiments of an actuating pre-bond structure 600 for a haptic response IC device 100 at various stages of manufacture, according to the present disclosure. Although FIGS. 8A through 8S are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. Further, in some embodiments, the various materials referenced with respect to FIGS. 8A through 8S may be the same corresponding materials as those discussed above in connection with FIG. 6.

FIG. 8A illustrates a layer of insulator material that will ultimately form insulator structure 604 formed (e.g., deposited) on first substrate 602. In some embodiments, the combination of insulator structure 604 and first substrate 602 may be available as a silicon-on-insulator (SOI) wafer as input to the following fabrication operations described below. In some embodiments, first substrate 602 may be approximately 750 microns (μm) in thickness at this stage of fabrication.

FIG. 8B illustrates the forming of a sacrificial layer 802 (e.g., a sacrificial oxide) on insulator structure 604. In some embodiments, a thickness of sacrificial layer 802 may be in the range of approximately one to fifteen μm.

FIG. 8C illustrates the inverting or flipping of the intermediate structure shown in FIG. 8B.

FIG. 8D illustrates the removal (e.g., grinding) of a portion of first substrate 602. In some embodiments, first substrate 602 is ground from a thickness of approximately 750 μm to somewhere in a range of approximately 700 μm to 200 μm.

FIG. 8E illustrates the inverting or flipping of the intermediate structure shown in FIG. 8D.

FIG. 8F illustrates the removal (e.g., dissolution by use of a solvent) of sacrificial layer 802. In some embodiments, the exposed insulator structure 604 may be further cleaned, rinsed, or otherwise processed.

FIG. 8G illustrates the forming (e.g., deposition) of an adhesion layer that ultimately forms a portion of barrier/adhesion structures 606. In some embodiments, the adhesion layer may have a thickness in a range of approximately 200 angstroms (Å) to 2000 Å.

FIG. 8H illustrates the forming (e.g., deposition, such as by sputtering) of a layer of conductive material that ultimately results in second electrode 608. In some embodiments, the conductive layer may have a thickness in a range of approximately 1000 Å to 10,000 Å.

FIG. 8I illustrates the forming (e.g., deposition) of a layer of piezoelectric material that ultimately results in piezoelectric element 610. In some embodiments, the piezoelectric material may have a thickness in a range of approximately 1000 Å to 10 μm.

FIG. 8J illustrates the forming (e.g., deposition, such as sputtering) of a layer of additional conductive material that ultimately results in first electrode 612. In some embodiments, the additional conductive material may have a thickness in a range of approximately 1000 Å to 10,000 Å.

FIG. 8K illustrates the removal (e.g., by photolithography and etching, as a form of metal-insulator-metal (MIM) patterning) of portions of the adhesion layer of FIG. 8G, the first conductive material of FIG. 8H, the piezoelectric material of FIG. 8I, and the additional conductive material of FIG. 8J to form second electrode 608, piezoelectric element 610, and first electrode 612 (e.g., to form the piezoelectric structures 302 of FIGS. 6, 7A, and 7B). In some embodiments, portions of the adhesion layer disposed on insulator structure 604 may also be removed.

FIG. 8L illustrates the forming (e.g., deposition) of additional adhesion material to further form barrier/adhesion structures 606. In some embodiments, the additional adhesion material may have a thickness in a range of approximately 200 Å to 5000 Å.

FIG. 8M illustrates the removal (e.g., by photolithography and etching) of portions of the additional adhesion material between and laterally external to second electrodes 608.

FIG. 8N illustrates the forming (e.g., deposition) of additional insulator material for insulator structures 604. In some embodiments, the additional insulator material may have a thickness in a range of approximately 3000 Å to 10000 Å.

FIG. 8O illustrates the removal (e.g., by photolithography and etching) of portions of insulator material and adhesion material to form vias 804 to facilitate subsequent connection to first electrodes 612 and second electrodes 608. In some embodiments, portions of the insulator material lying directly atop first substrate 602 may also be removed.

FIG. 8P illustrates the forming (e.g., deposition) of conductive material 806 that ultimately forms the conductive pads and bonding pad associated with actuating pre-bond structure 600 of FIGS. 7A and 7B. In some embodiments, conductive material 806 may have a thickness in a range of approximately 1000 Å to 40000 Å.

FIG. 8Q illustrates the removal (e.g., by photolithography and etching) of portions of the conductive material of FIG. 8P to form first conductive pads 614, second conductive pads 616, and bonding pad 618.

FIG. 8R illustrates the forming (e.g., deposition) of passivation layer 620. In some embodiments, passivation layer 620 may have a thickness in a range of approximately 3000 Å to 10000 Å.

FIG. 8S illustrates the removal (e.g., by photolithography and etching) of portions of passivation layer 620 to create contact openings for first conductive pads 614, second conductive pads 616, and bonding pad 618. Additionally, in some embodiments, some extraneous portions of passivation layer 620 covering insulator structure 604 and first substrate 602 may also be removed. Such operations, in some embodiments, may result in the creation of actuating pre-bond structure 600 of FIGS. 7A and 7B.

FIGS. 9A and 9B illustrate a side view and a plan view, respectively, of some embodiments of a capping structure 900 for a haptic response IC device 100, according to the present disclosure. More specifically, FIG. 9B is presented as looking upward toward a lower surface of capping structure 900, as presented in FIG. 9A. As shown, capping structure 900 is in a state just prior to combining with actuating pre-bond structure 600 of FIG. 8S and subsequent processing to create IC device 100 of FIG. 6. In some embodiments, a second substrate 502 and an adjacent insulating/adhesion structure 626 may include or define trenches 632 that extend downward through second substrate 502 and insulating/adhesion structure 626. In addition, in some embodiments, second substrate 502 defines or includes a cavity 630 that extends upward partially through second substrate 502. In some embodiments, second substrate 502 may include silicon (Si) or another semiconductor material.

Further, in some embodiments, capping structure 900 may include a plurality of bump pad structures 622 and 624 coupled with insulating/adhesion structure 626, where each of bump pad structures 624 are disposed at least partially within an associated trench 632, while bump pad structures 622 are disposed at an exposed side of insulating/adhesion structure 626.

In some embodiments, as indicated in FIG. 9B, bump pad structure 624 may form an open rectangular structure routed between corresponding pairs of bump pad structures 622, thus substantially matching the layout of bonding pad 618 of FIG. 7B. Further, bump pad structures 624 may be laterally aligned to corresponding with first conductive pads 614 and second conductive pads 616. In some embodiments, various possible materials for insulating/adhesion structure 626 and bump pad structures 622 and 624 may be as discussed above in connection with FIG. 6.

FIGS. 10A through 10K illustrate various side views of some embodiments of a capping structure 900 for a haptic response IC device 100 at various stages of manufacture, according to the present disclosure. Although FIGS. 10A through 10K are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. Further, in some embodiments, the various materials referenced with respect to FIGS. 10A through 10K may be the same corresponding materials as those discussed above in connection with FIG. 6.

FIG. 10A illustrates a layer of insulation material that will ultimately form insulating/adhesion structure 626 formed (e.g., deposited) on second substrate 502. In some embodiments, the combination of insulating/adhesion structure 626 and second substrate 502 may be available as an SOI wafer as input to the following fabrication operations described below. In some embodiments, the layer of insulation material has a thickness in a range of approximately 1000 Å to 20,000 Å.

FIG. 10B illustrates the removal (e.g., by photolithography and etching) of portions of insulating/adhesion structure 626 to form vias 1001 that align with first conductive pads 614 and second conductive pads 616 of actuating pre-bond structure 600 of FIGS. 7A and 7B.

FIG. 10C illustrates the forming (e.g., deposition) of a layer of conductive material 1002 on insulating/adhesion structure 626 for bump pad structures 622 and 624 of FIGS. 9A and 9B. In some embodiments, the layer of conductive material 1002 has a thickness in a range of approximately 1000 Å to 20,000 Å.

FIG. 10D illustrates the removal (e.g., by photolithography and etching) of portions of the layer of conductive material 1002 to form bump pad structures 622 and 624.

FIG. 10E illustrates the forming (e.g., deposition) of a layer of adhesive 1004 (e.g., a double adhesive) over insulating/adhesion structures 626 and bump pad structures 622 and 624.

FIG. 10F illustrates the bonding of a glass structure 1006 to the layer of adhesive 1004.

FIG. 10G illustrates the inversion or flipping of the intermediate structure depicted in FIG. 10F.

FIG. 10H illustrates the removal (e.g., grinding) of second substrate 502 to reduce a thickness of second substrate 502 to a range of approximately 500 μm to 200 μm.

FIG. 10I illustrates the removal (e.g., by photolithography and deep trench etching) of portions of second substrate 502 to form trenches 632 extending to bump pad structures 624.

FIG. 10J illustrates the inversion or flipping of the intermediate structure of FIG. 10I and subsequent removal (e.g., by laser de-bonding) of glass structure 1006 and adhesive 1004. In some embodiments, a further cleansing operation (e.g., using a solvent to remove remaining residue, and performing a subsequent wet rinse process) may be performed thereafter.

FIG. 10K illustrates the removal (e.g., by lithography and etching) of a portion of second substrate 502 to form cavity 630, resulting in the creation of capping structure 900.

FIGS. 11A through 11F illustrate various side views of some embodiments of a haptic response IC device 100 at various stages of manufacture using an actuating pre-bond structure (e.g., actuating pre-bond structure 600 of FIG. 8S, as described above) and a capping structure (e.g., capping structure 900 of FIG. 10K, as discussed above), according to the present disclosure. Although FIGS. 11A through 11F are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 11A illustrates the joining (e.g., by way of fusion bonding bump pad structures 622 and 624 with first conductive pads 614, second conductive pads 616, and bonding pad 618) of capping structure 900 of FIG. 10K and actuating pre-bond structure 600 of FIG. 8S.

FIG. 11B illustrates the flipping or inversion of the intermediate structure of FIG. 11A.

FIG. 11C illustrates the removal (e.g., by lithography and etching) of a portion of an exposed side of first substrate 602 to create an opening 1102 that extends cavity 630 upward through first substrate 602.

FIG. 11D illustrates the forming (e.g., deposition) of an adhesive 603 on the exposed side of first substrate 602 near and about cavity 630.

FIG. 11E illustrates the filling of cavity 630 with a fluid 506 (e.g., a non-compressible liquid).

FIG. 11F illustrates the sealing of cavity 630 by affixing a membrane 504 (e.g., a flexible film or other membrane) using adhesive 603 to cover an opening of cavity 630 to retain fluid 506 therein.

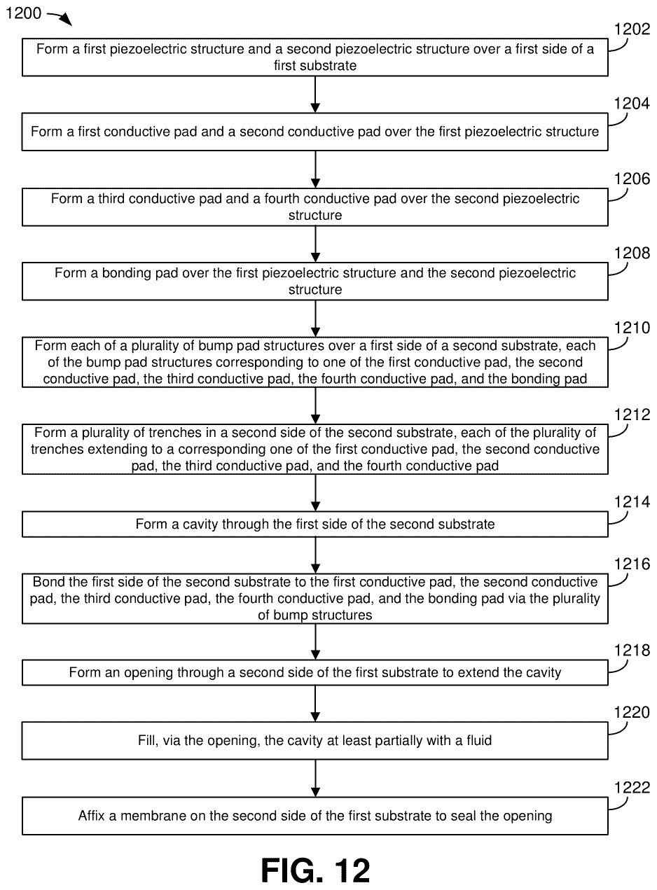

FIG. 12 illustrates a methodology 1200 of forming a haptic response IC device (e.g., IC device 100 of FIGS. 6 and 11F), according to some embodiments of the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1202, for example, a first piezoelectric structure and a second piezoelectric structure (e.g., piezoelectric structures 302 of FIG. 6) are formed over a first side of a first substrate (e.g., first substrate 602 of FIG. 6). In some embodiments, each of the first piezoelectric structure and the second piezoelectric structure may include a first electrode (e.g., first electrode 612 of FIG. 6), a second electrode (e.g., second electrode 608 of FIG. 6), and a piezoelectric element (e.g., piezoelectric element 610 of FIG. 6), where the piezoelectric element is on the second electrode, and where the first electrode is on the piezoelectric element. FIGS. 8G through 8K illustrate cross-sectional views of some embodiments corresponding to Act 1202.

At Act 1204, a first conductive pad (e.g., first conductive pad 614 for the first piezoelectric structure 302 of FIG. 6) and a second conductive pad (e.g., second conductive pad 616 for the first piezoelectric structure 302 of FIG. 6) are formed over the first piezoelectric structure. At Act 1206, a third conductive pad (e.g., first conductive pad 614 for the second piezoelectric structure 302 of FIG. 6) and a fourth conductive pad (e.g., second conductive pad 616 for the second piezoelectric structure 302 of FIG. 6) are formed over the second piezoelectric structure. At Act 1208, a bonding pad (e.g., bonding pad 618 of FIG. 6) is formed over the first piezoelectric structure and the second piezoelectric structure. FIGS. 8O through 8Q illustrate cross-sectional views of some embodiments corresponding to Acts 1204, 1206, and 1208.

At Act 1210, each of a plurality of bump pad structures (e.g., bump pad structures 622 and 624 of FIG. 6) is formed over a first side of a second substrate (e.g., second substrate 502 of FIG. 6), each of the bump pad structures corresponding to one of the first conductive pad, the second conductive pad, the third conductive pad, the fourth conductive pad, and the bonding pad. FIGS. 10B through 10D illustrate cross-sectional views of some embodiments corresponding to Act 1210.

At Act 1212, a plurality of trenches (e.g., trenches 632 of FIG. 6) is formed in a second side of the second substrate, each of the plurality of the trenches extending to a corresponding one of the first conductive pad, the second conductive pad, the third conductive pad, and the fourth conductive pad. FIG. 10I illustrates a cross-sectional view of some embodiments corresponding to Act 1212.

At Act 1214, a cavity (e.g., cavity 630 of FIG. 6) is formed through the first side of the second substrate. FIG. 10K illustrates a cross-sectional view of some embodiments corresponding to Act 1214.

At Act 1216, the first side of the second substrate is bonded to the first conductive pad, the second conductive pad, the third conductive pad, the fourth conductive pad, and the bonding pad via the plurality of bump pad structures. FIG. 11A illustrates a cross-sectional view of some embodiments corresponding to Act 1216.

At Act 1218, an opening (e.g., opening 1102 of FIG. 11C) is formed through a second side of the first substrate to extend the cavity. FIG. 11C illustrates a cross-sectional view of some embodiments corresponding to Act 1218.

At Act 1220, the cavity is filled via the opening at least partially with a fluid (e.g., fluid 506 of FIG. 6). FIG. 11E illustrates a cross-sectional view of some embodiments corresponding to Act 1220.

At Act 1222, a membrane (e.g., membrane 504 of FIG. 6) is affixed on the second side of the first substrate to seal the opening. FIG. 11F illustrates a cross-sectional view of some embodiments corresponding to Act 1222.

Some embodiments relate to an IC device. The IC device includes a substrate structure, a first piezoelectric structure, and a second piezoelectric structure. The substrate structure includes a cavity extending downward from an upper side of the substrate structure. The first piezoelectric structure and the second piezoelectric structure are disposed within the substrate structure at opposing lateral sides of the substrate structure and extend laterally into the cavity toward each other. Each of the first piezoelectric structure and the second piezoelectric structure include a first electrode, a piezoelectric element disposed on the first electrode, and a second electrode disposed on the piezoelectric element. The IC device further includes a fluid disposed in the cavity, and a membrane coupled to the upper side of the substrate structure, the membrane sealing the cavity and retaining the fluid.

Some embodiments relate to another IC device. The IC device includes a first substrate and a second substrate. The first substrate is disposed over the second substrate. The first substrate and the second substrate form a cavity having a opening at an upper side of the first substrate. The IC device also includes a first piezoelectric structure and a second piezoelectric structure disposed between the first substrate and the second substrate. Each of the first piezoelectric structure and the second piezoelectric structure extend laterally toward a central region of the cavity. Each of the first piezoelectric structure and the second piezoelectric structure include a first electrode, a second electrode disposed over the first electrode, and a piezoelectric element disposed between the first electrode and the second electrode. Each of the first electrode, the second electrode, and the piezoelectric element have a rectangular shape in a plan view of the IC device. The IC device further includes a fluid filling at least a portion of the cavity, and a membrane covering the opening to retain the fluid within the cavity.

Some embodiments relate to a method. The method includes forming a first piezoelectric structure and a second piezoelectric structure over a first side of a first substrate, wherein each of the first piezoelectric structure and the second piezoelectric structure comprises a first electrode, a second electrode, and a piezoelectric element, wherein the piezoelectric element is on the second electrode, and wherein the first electrode is on the piezoelectric element; forming a first conductive pad and a second conductive pad over the first piezoelectric structure; forming a third conductive pad and a fourth conductive pad over the second piezoelectric structure; forming a bonding pad over the first piezoelectric structure and the second piezoelectric structure; forming each of a plurality of bump pad structures over a first side of a second substrate, each of the bump pad structures corresponding to one of the first conductive pad, the second conductive pad, the third conductive pad, the fourth conductive pad, and the bonding pad; forming a plurality of trenches in a second side of the second substrate that extend to at least some of the plurality of bump pad structures, each of the plurality of the trenches corresponding to one of the first conductive pad, the second conductive pad, the third conductive pad, and the fourth conductive pad; forming a cavity through the first side of the second substrate; bonding the first side of the second substrate to the first conductive pad, the second conductive pad, the third conductive pad, the fourth conductive pad, and the bonding pad via the plurality of bump pad structures; forming an opening through a second side of the first substrate to extend the cavity; filling, via the opening, the cavity at least partially with a fluid; and affixing a membrane on the second side of the first substrate to seal the opening.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate structure including a cavity extending downward from an upper side of the substrate structure;
a first piezoelectric structure and a second piezoelectric structure disposed within the substrate structure at opposing lateral sides of the substrate structure and extending laterally into the cavity toward each other, each of the first piezoelectric structure and the second piezoelectric structure comprising:
a first electrode;
a piezoelectric element disposed on the first electrode; and
a second electrode disposed on the piezoelectric element;
a fluid disposed in the cavity; and
a membrane coupled to the upper side of the substrate structure, the membrane sealing the cavity and retaining the fluid.

2. The IC device of claim 1, wherein the fluid comprises a non-compressible liquid.

3. The IC device of claim 1, further comprising:
a first conductive pad in contact with the first electrode of the first piezoelectric structure;
a second conductive pad in contact with the second electrode of the first piezoelectric structure;
a third conductive pad in contact with the first electrode of the second piezoelectric structure; and
a fourth conductive pad in contact with the second electrode of the second piezoelectric structure.

4. The IC device of claim 1, wherein:
the substrate structure comprises a first substrate and a second substrate, wherein the first substrate is disposed over the second substrate;
the first substrate comprises the upper side of the substrate structure;
the first piezoelectric structure and the second piezoelectric structure are disposed between the first substrate and the second substrate; and
the first substrate and the second substrate each comprise a portion of the cavity.

5. The IC device of claim 4, further comprising:
a first conductive pad in contact with the first electrode of the first piezoelectric structure;
a second conductive pad in contact with the second electrode of the first piezoelectric structure;
a third conductive pad in contact with the first electrode of the second piezoelectric structure;
a fourth conductive pad in contact with the second electrode of the second piezoelectric structure; and
a bonding pad coupling the first substrate to the second substrate, wherein the bonding pad is disposed laterally between the first conductive pad and the second conductive pad and laterally between the third conductive pad and the fourth conductive pad.

6. The IC device of claim 5, wherein the bonding pad laterally surrounds the cavity.

7. The IC device of claim 5, further comprising:
a passivation layer covering at least a portion of the first conductive pad, the second conductive pad, the third conductive pad, the fourth conductive pad, and the bonding pad.

8. The IC device of claim 4, further comprising:
a bonding pad coupling the first substrate to the second substrate, wherein the bonding pad laterally surrounds the cavity.

9. The IC device of claim 1, further comprising:
a first insulation layer laterally and vertically surrounding the first piezoelectric structure; and
a second insulation layer laterally and vertically surrounding the second piezoelectric structure.

10. The IC device of claim 9, further comprising:
a first adhesion layer coupling the first insulation layer to the first piezoelectric structure; and
a second adhesion layer coupling the second insulation layer to the second piezoelectric structure.

11. An integrated circuit (IC) device, comprising:
a first substrate and a second substrate, the first substrate being disposed over the second substrate, the first substrate and the second substrate forming a cavity having an opening at an upper side of the first substrate;
a first piezoelectric structure and a second piezoelectric structure disposed between the first substrate and the second substrate, each of the first piezoelectric structure and the second piezoelectric structure extending laterally toward a central region of the cavity, each of the first piezoelectric structure and the second piezoelectric structure comprising:
a first electrode;
a second electrode disposed over the first electrode; and
a piezoelectric element disposed between the first electrode and the second electrode, wherein each of the first electrode, the second electrode, and the piezoelectric element have a rectangular shape in a plan view of the IC device;
a fluid filling at least a portion of the cavity; and
a membrane covering the opening to retain the fluid within the cavity.

12. The IC device of claim 11, wherein:
an area of the piezoelectric element in the plan view of the IC device is greater than an area of the first electrode in the plan view of the IC device; and
an area of the second electrode in the plan view of the IC device is greater than the area of the piezoelectric element in the plan view of the IC device.

13. The IC device of claim 12, wherein:
a perimeter of the piezoelectric element in the plan view of the IC device encloses a perimeter of the first electrode in the plan view of the IC device; and
a perimeter of the second electrode in the plan view of the IC device encloses the perimeter of the piezoelectric element in the plan view of the IC device.

14. The IC device of claim 11, further comprising:
a first conductive pad in contact with the first electrode of the first piezoelectric structure;
a second conductive pad in contact with the second electrode of the first piezoelectric structure;
a third conductive pad in contact with the first electrode of the second piezoelectric structure; and
a fourth conductive pad in contact with the second electrode of the second piezoelectric structure.

15. The IC device of claim 14, further comprising a bonding pad coupling the first substrate to the second substrate, wherein the bonding pad is disposed laterally between the first conductive pad and the second conductive pad and between the third conductive pad and the fourth conductive pad.

16. The IC device of claim 14, further comprising:
a plurality of bump pad structures, each of the plurality of bump pad structures contacting a corresponding one of the first conductive pad, the second conductive pad, the third conductive pad, and the fourth conductive pad;
wherein the first substrate comprises a plurality of trenches, each of the plurality of trenches extending upward from a lower side of the second substrate to a corresponding one of the plurality of bump pad structures.

17. A method comprising:
forming a first piezoelectric structure and a second piezoelectric structure over a first side of a first substrate, wherein each of the first piezoelectric structure and the second piezoelectric structure comprises a first electrode, a second electrode, and a piezoelectric element, wherein the piezoelectric element is on the second electrode, and wherein the first electrode is on the piezoelectric element;
forming a first conductive pad and a second conductive pad over the first piezoelectric structure;
forming a third conductive pad and a fourth conductive pad over the second piezoelectric structure;
forming a bonding pad over the first piezoelectric structure and the second piezoelectric structure;
forming each of a plurality of bump pad structures over a first side of a second substrate, each of the bump pad structures corresponding to one of the first conductive pad, the second conductive pad, the third conductive pad, the fourth conductive pad, and the bonding pad;
forming a plurality of trenches in a second side of the second substrate, each of the plurality of the trenches extending to a corresponding one of the first conductive pad, the second conductive pad, the third conductive pad, and the fourth conductive pad;
forming a cavity through the first side of the second substrate;
bonding the first side of the second substrate to the first conductive pad, the second conductive pad, the third conductive pad, the fourth conductive pad, and the bonding pad via the plurality of bump pad structures;
forming an opening through a second side of the first substrate to extend the cavity;
filling, via the opening, the cavity at least partially with a fluid; and
affixing a membrane on the second side of the first substrate to seal the opening.

18. The method of claim 17, further comprising:
forming a first insulation layer at least on the first side of the first substrate prior to forming the first piezoelectric structure and the second piezoelectric structure, wherein the opening extends at least to the first insulation layer.

19. The method of claim 18, further comprising:
forming a second insulation layer over the first piezoelectric structure and the second piezoelectric structure.

20. The method of claim 17, wherein forming the first piezoelectric structure and the second piezoelectric structure comprises:
forming a first conductive layer over the first side of the first substrate;
forming a piezoelectric layer on the first conductive layer;
forming a second conductive layer over the piezoelectric layer; and
selectively removing material from the second conductive layer, the piezoelectric layer, and the first conductive layer to form the first piezoelectric structure and the second piezoelectric structure.
